(19) United States
(12) Patent Application Publication
(10) Pub. No.: US 2015/0318442 A1
(43) Pub. Date: Nov. 5, 2015

(54) ELECTROLUMINESCENT DEVICES AND APPLICATIONS THEREOF

(71) Applicant: PURELUX INC., Charlotte, NC (US)

(72) Inventor: Carl RYDEN, Cary, NC (US)

(21) Appl. No.: 14/647,353

(22) PCT Filed: Nov. 25, 2013
(86) PCT No.: PCT/US2013/071714

§ 371 Date: May 26, 2015

Related U.S. Application Data
(60) Provisional application No. 61/729,801, filed on Nov. 26, 2012.

(51) Int. Cl. H01L 33/36; H01L 33/00

(52) U.S. Cl. CPC H01L 33/36; H01L 33/0054

(57) ABSTRACT

In one aspect, electroluminescent architectures and devices are described herein. An electroluminescent device, in some embodiments, comprises a first electrode, a second electrode and at least one light emitting layer comprising charge carrier injection structures in contact with an electroluminescent phase in a predetermined spatial distribution, the electroluminescent phase comprising luminescent centers in a semiconductor matrix.

### RELATED APPLICATION DATA

The present application claims priority pursuant to 35 U.S.C. §119(e) to U.S. Provisional Patent Application Ser. No. 61/729,801 filed Nov. 26, 2012, which is hereby incorporated by reference in its entirety.

### FIELD

The present invention relates to lighting devices and, in particular, to electroluminescent lighting devices.

### BACKGROUND

Currently available lighting systems include incandescent, fluorescent, halogen, and high intensity discharge sources of light. Disadvantages exist within lighting systems based on these illumination sources, many related to efficiency. Presently, only about 30% of the electrical energy consumed in lighting applications results in the production of light. The remainder of the electrical energy is dissipated by non-radiative processes such as heat generation. Incandescent light sources, for example, consume 45% of all lighting energy but only produce 14% of the total light generated. Moreover, fluorescent lamps are only about four times as efficient as incandescent sources and still suffer from inherent energy loss.

New lighting technologies are being developed in attempts to overcome the disadvantages of current lighting systems. One such technology is based on light emitting diodes (LEDs). In general, light emitting diodes are constructed from semiconductor materials and, when forward biased, emit radiation. Depending on the semiconductor material used, the emitted radiation can fall within the ultraviolet, visible or infrared regions of the electromagnetic spectrum. Light emitting diodes offer the advantages of enhanced lifetimes, reduced heat production, and rapid illumination times.

However, light emitting diodes require a direct current source for operation, which is fundamentally inconsistent with the alternating current provided by residential and commercial electrical outlets. As a result, various rectifier constructions are necessary to adapt present light emitting diodes to the alternating current sources found in residential and commercial lighting applications. The necessity of a rectifier increases production time and cost for lighting systems incorporating light emitting diodes, thereby limiting widespread application of such lighting systems.

### SUMMARY

In one aspect, electroluminescent architectures and devices are described herein which, in some embodiments, may overcome or mitigate one or more disadvantages of previous lighting technologies, including direct current based light emitting diodes.

An electroluminescent device described herein comprises a first electrode, a second electrode and at least one light emitting layer comprising charge carrier injection structures in contact with an electroluminescent phase in a predetermined spatial distribution, the electroluminescent phase comprising luminescent centers in a semiconductor matrix. The carrier injection structures, in some embodiments, are electrically connected to the first electrode. Alternatively, in some embodiments, the carrier injection structures are electrically isolated from the first electrode.

In another aspect, an electroluminescent device described herein comprises a plurality of light emitting layers, the light emitting layers comprising a first electrode, a second electrode and charge carrier injection structures in contact with an electroluminescent phase in a predetermined spatial distribution, the electroluminescent phase comprising luminescent centers in a semiconductor matrix. Light emitting layers of the electroluminescent device, in some embodiments, are separated by one or more dielectric layers.

In another aspect, methods of making electroluminescent devices are described herein. A method of making an electroluminescent device comprises providing a substrate and depositing over the substrate a first electroluminescent layer comprising carrier injection structures and an electroluminescent phase comprising luminescent centers in a semiconductor matrix, wherein the carrier injection structures are placed in contact with the electroluminescent phase in a predetermined spatial distribution. In some embodiments, a method of making an electroluminescent device further comprises depositing over the first electroluminescent layer at least one additional electroluminescent layer comprising carrier injection structures and an electroluminescent phase comprising luminescent centers in a semiconductor matrix, wherein the carrier injection structures are placed in contact with the electroluminescent phase in predetermined spatial distribution. In some embodiments, an additional electroluminescent layer is separated from an underlying electroluminescent layer by one or more dielectric layers.

In another aspect, methods of generating electromagnetic radiation are described herein. A method of generating electromagnetic radiation, in some embodiments, comprises providing an electroluminescent device comprising a first electrode, a second electrode and at least one light emitting layer comprising charge carrier injection structures in contact with an electroluminescent phase in a predetermined spatial distribution, wherein the electroluminescent phase comprises luminescent centers in a semiconductor matrix. An electric field is applied to the light emitting layer by the first and second electrodes, and charge carriers are injected into the semiconductor matrix by the charge carrier injection structures. The electric field can be generated by application of an alternating current voltage to the electrodes or direct current voltage to the electrodes. The injected charge carriers are subsequently relaxed through one or more radiative relaxation pathways at the luminescent centers for the generation of electromagnetic radiation.

In some embodiments, the carrier injection structures are electrically connected to the first electrode, thereby receiving carriers from the first electrode for injection into the semiconductor matrix. Alternatively, the carrier injection structures are electrically isolated from the first electrode, thereby precluding or inhibiting receipt of carriers from the electrode for injection into the semiconductor matrix.

These and other embodiments are described in greater detail in the detailed description which follows.

### BRIEF DESCRIPTION OF THE DRAWINGS

FIG. 1 illustrates a top cross-sectional view of an electroluminescent device according to one embodiment described herein.

FIG. 2 illustrates a side cross-sectional view of an electroluminescent device according to one embodiment described herein.

FIG. 3 illustrates a top cross-sectional view of an electroluminescent device according to one embodiment described herein.

FIG. 4 illustrates a side cross-sectional view of an electroluminescent device according to one embodiment described herein.

FIG. 5 illustrates a side cross-sectional view of an electroluminescent device according to one embodiment described herein.

### DETAILED DESCRIPTION

Embodiments described herein can be understood more readily by reference to the following detailed description and examples and their previous and following descriptions. Elements, apparatus and methods described herein, however, are not limited to the specific embodiments presented in the detailed description and examples. It should be recognized that these embodiments are merely illustrative of the principles of the present invention. Numerous modifications and adaptations will be readily apparent to those of skill in the art without departing from the spirit and scope of the invention.

### I. Electroluminescent Devices

In one aspect, electroluminescent architectures and devices are described herein which, in some embodiments, can provide one or more advantages over current lighting technologies. An electroluminescent device, in some embodiments, comprises a first electrode, a second electrode and at least one light emitting layer comprising charge carrier injection structures in contact with an electroluminescent phase in a predetermined spatial distribution, the electroluminescent phase comprising luminescent centers in a semiconductor matrix. The carrier injection structures, in some embodiments, are electrically connected to the first electrode. Alternatively, in some embodiments, the carrier injection structures are electrically isolated from the first electrode.

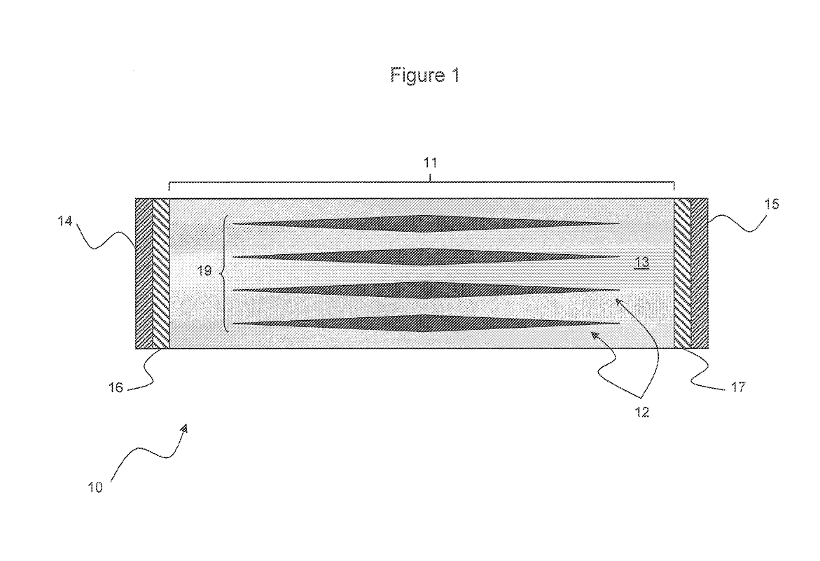

FIG. 1 illustrates a top cross-sectional view of an electroluminescent device according to one embodiment described herein. As illustrated in FIG. 1, the electroluminescent device (10) comprises a light emitting layer (11) comprising charge carrier injection structures (12) in contact with an electroluminescent phase (13) in a predetermined spatial distribution (19). In the embodiment of FIG. 1, the predetermined spatial distribution (19) is a predetermined pattern of the carrier injection structures (12) contacting the electroluminescent phase (13). Further, the carrier injection structures (12) can be provided in predetermined dimensions and/or geometries. In FIG. 1, the carrier injection structures (12) are provided an acicular or tapered geometry.

The electroluminescent device (10) further comprises a first electrode (14) and second electrode (15) for application of an electric field across the carrier injection structures (12) and electroluminescent phase (13). In the embodiment of FIG. 1, the carrier injection structures (12) and electroluminescent phase (13) are electrically isolated from the first (14) and second (15) electrodes by dielectric layers (16, 17).

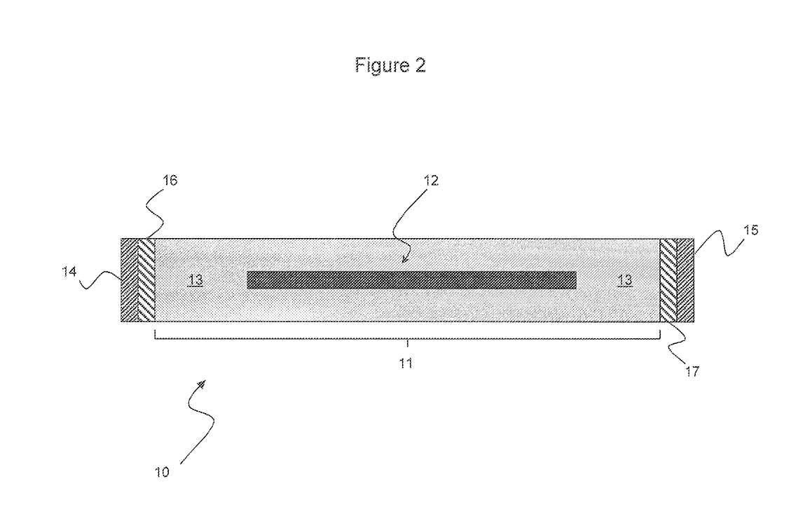

FIG. 2 illustrates a side cross-sectional view of the electroluminescent device of FIG. 1. As illustrated in FIG. 2, the carrier injection structures (12) are contained within the layer of electroluminescent phase (13) and demonstrate an orientation wherein the major axes of the carrier injection structures (12) are aligned or substantially aligned with the direction of the electric field applied by the first (14) and second (15) electrodes. Alternatively, in some embodiments, the major axes of the carrier injection structures (12) are not aligned with the direction of the electric field applied by the first (14) and second (15) electrodes.

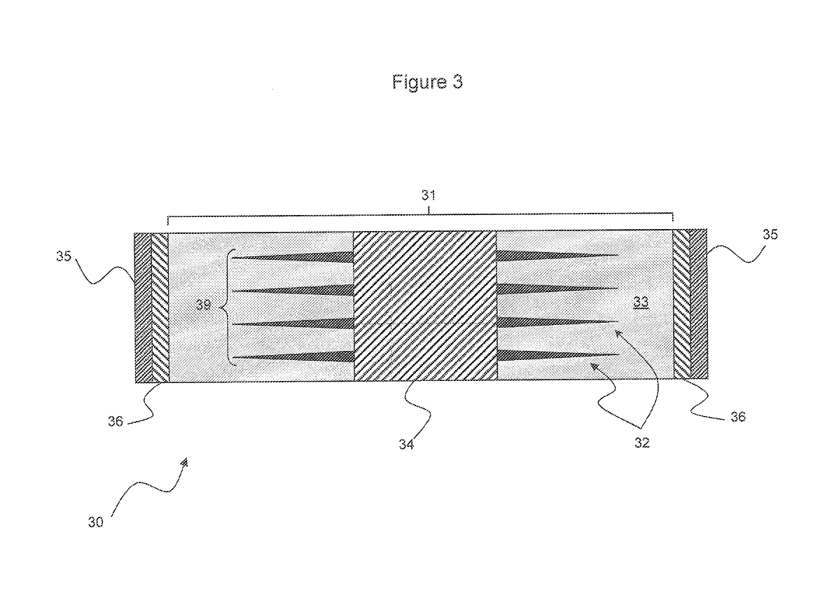

FIG. 3 illustrates a top cross-sectional view of an electroluminescent device according to another embodiment described herein. The electroluminescent device (30) comprises a light emitting layer (31) comprising carrier injection structures (32) in contact with an electroluminescent phase (33) in a predetermined spatial distribution (39). In the embodiment of FIG. 3, the predetermined spatial distribution (39) is a predetermined pattern of the carrier injection structures (32) in contact with the electroluminescent phase (33). Similar to FIGS. 1 and 2, the carrier injection structures (32) of the electroluminescent device (30) display an acicular or tapered geometry.

The electroluminescent device further comprises first (34) and second (35) electrodes for application of an electric field across the carrier injection structures (32) and electroluminescent phase (33). In the embodiment of FIG. 3, the first electrode (34) is in electrical contact with the carrier injection structures (32). While not required, one or more dielectric layers (36) separate the second electrode (35) from the electroluminescent phase (33). Use of a dielectric layers (36) between the second electrode (35) and the electroluminescent phase (33) can inhibit or preclude current flow-through or breakdown of the electroluminescent device (30).

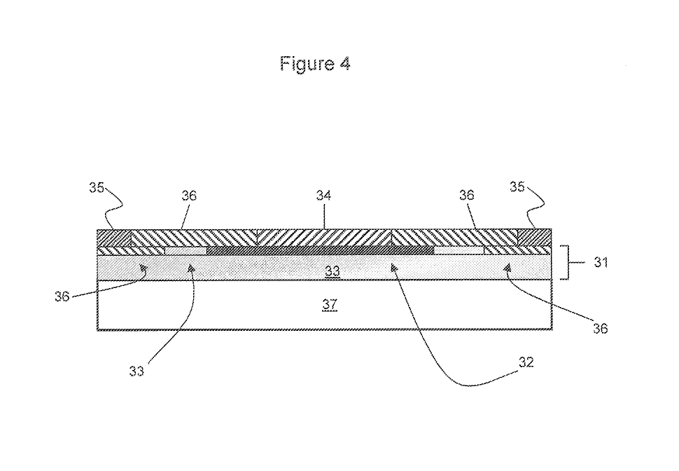

FIG. 4 illustrates a side cross-sectional view of the electroluminescent device (30) of FIG. 3. As illustrated in FIG. 4, the first electrode (34) is in electrical contact with the carrier injection structures (32). The first electrode (34), however, is not commensurate or co-extensive with the predetermined spatial distribution of the carrier injection structures (32). In the embodiment of FIGS. 3 and 4, the first electrode (34) contacts only a portion or section of each of the carrier injection structures (32). Alternatively, in some embodiments, the first electrode (34) is commensurate or co-extensive with the carrier injection structures (32). Dielectric layers (36) separate the electroluminescent phase (33) from the second electrode (35). The electroluminescent device (30) further comprises a radiation transmissive substrate (37) over which the light emitting layer (31) is positioned.

Turning now to specific components, an electroluminescent device described herein comprises at least one light emitting layer comprising charge carrier injection structures in contact with an electroluminescent phase in a predetermined spatial distribution. The electroluminescent phase of the light emitting layer comprises luminescent centers in a semiconductor matrix. The semiconductor matrix of an electroluminescent phase can comprise any semiconductor material not inconsistent with the objectives of the present invention. In some embodiments, the semiconductor matrix is a compound semiconductor. Suitable compound semiconductors for the matrix, in some embodiments, are selected from the group consisting of II/VI and III/V semiconductor materials. For example, in one embodiment, the semiconductor matrix of the electroluminescent phase described herein is zinc sulfide (ZnS). Further, suitable semiconductor materials for the matrix demonstrate a sufficiently wide bandgap to prevent absorption of radiation generated by the luminescent centers dispersed therein.

The semiconductor matrix can have any desired morphology not inconsistent with the objectives of the present invention. The semiconductor matrix, for example, can be one or more polycrystalline layers of semiconductor material. In one embodiment, the semiconductor matrix comprises one or more layers of polycrystalline ZnS. In being polycrystalline, the semiconductor matrix can demonstrate grain sizes suitable for electronic interaction with the charge carrier injection structures for the production of light at the luminescent centers of the matrix. Further, in being polycrystalline, grain boundaries are evident between grains of the semiconductor matrix, thereby differentiating electroluminescent structures wherein discrete or individual crystalline grains are dispersed in an organic binder, such as a dielectric binder. Alternatively, in some embodiments, the semiconductor matrix can be single crystalline.

As described herein, the semiconductor matrix comprises luminescent centers dispersed therein. Luminescent centers are sites or locations in the semiconductor matrix where charge carriers are relaxed by one or more radiative pathways. Luminescent centers can include defects or trap states for localizing injected charge carriers for radiative recombination. Luminescent centers can also include one or more atomic species doped or otherwise incorporated into the lattice of the semiconductor matrix as an activator. Suitable activators include ions of transition metals, rare earth metals or mixtures thereof. In some embodiments, for example, activator of the semiconductor matrix comprises one or more metal ions selected from Groups IB, IIIB, VIIB, VIIIB and IIIA of the Periodic Table. Groups of the Periodic Table described herein are identified according to the CAS designation. Activator, in some embodiments, comprises ions of copper, manganese, silver, gadolinium, dysprosium, europium, samarium, terbium or thulium or mixtures thereof. Additionally, the semiconductor matrix can further comprise co-activator chemical species. Co-activator chemical species work in conjunction with activator for the relaxation of charge carriers by one or more radiative pathways. Co-activator can comprise ionic species selected from Groups IIIA and VIIA of the Periodic Table. For example, co-activator can comprise ions of aluminum, indium, chlorine or iodine or mixtures thereof. In some embodiments, co-activator can be present in the semiconductor matrix in the absence of activator. In such embodiments, the co-activator can assist in self-radiative relaxation processes of the semiconductor matrix in response to charge carriers introduced by the carrier injection structures. For example, in one embodiment, chloride co-activator is present in a ZnS matrix in the absence of activator.

The specific identity and amount of activator incorporated into the lattice of the semiconductor matrix for the establishment of luminescent centers can be selected according to several factors, including the chemical identity of the semiconductor matrix and the desired color of electroluminescence. In some embodiments, for example, manganese activator is provided to a ZnS matrix in an amount up to about 4 atomic percent. Moreover, the specific identity and amount of co-activator incorporated into the semiconductor matrix can be selected according to several considerations, including the identities of the activator and semiconductor matrix as well as the desired color and efficiency of electroluminescence.

The semiconductor matrix having activator and/or co-activator dispersed throughout the lattice can be an n-type semiconductor or a p-type semiconductor, depending on the identity of the activator and/or co-activator. For example, manganese doped ZnS can provide an n-type semiconductor matrix.

The semiconductor matrix comprising activator and/or co-activator can have any thickness not inconsistent with the objectives of the present invention. In some embodiments, the semiconductor matrix has a thickness of about 10 nm to about 1 μm. The semiconductor matrix can have a thickness of 10 nm to 200 nm. In some embodiments, the semiconductor matrix has a thickness of 50 nm to 500 nm.

A light emitting layer of an electroluminescent device also comprises carrier injection structures in contact with the electroluminescent phase in a predetermined spatial arrangement. Carrier injection structures are operable to provide charge carriers, holes and/or electrons, to the electroluminescent phase in response to application of an electric field to the light emitting layer. The electric field can be generated by application of an alternating current voltage or direct current voltage to the device electrodes. The charge carriers provided by the carrier injection structures are subsequently relaxed at luminescent centers in the semiconductor matrix by one or more radiative relaxation pathways. The carrier injection structures, therefore, can demonstrate one or more geometries suitable for electric field concentration at tips or ends of the structures. Carrier injection structures, for example, have acicular geometries or tapered geometries. In some embodiments, carrier injection structures demonstrate pyramidal or triangular geometries.

Further, dimensions of the carrier injection structures are suitable for electric field concentration. In some embodiments, carrier injection structures have one or more minor structural axes on the order of nanometers or tens of nanometers and a major structural axis on the order of hundreds of nanometers or microns. The major structural axis of a carrier injection structure corresponds to the largest dimension of the injection structure while the minor structural axes correspond to remaining smaller dimensions of the injection structure. For example, the major structural axis of a carrier injection structure having an acicular geometry is the length of the structure with the minor structural axis being the diameter of the structure. As discussed further herein, major structural axes of carrier injection structures can be aligned with the direction of the electric field applied by the first and second electrodes of the electroluminescent device. By demonstrating geometries and dimensions operable for electric field concentration, carrier injection structures described herein, in some embodiments, can provide high electric fields at tips or ends of the structures of about 10⁴ V/cm to 10⁶ V/cm. In some embodiments, carrier injection structures can provide electric fields of 10⁵ V/cm to 10⁶ V/cm.

Carrier injection structures can be fabricated from any material not inconsistent with the objectives of the present invention. In some embodiments, carrier injection structures are formed of a semiconductor material. Semiconducting materials suitable for carrier injection structures can comprise metal sulfides as well as II/VI and III/V materials. In some embodiments, for example, a metal sulfide semiconductor material for carrier injection structures is copper sulfide (CuₓS) wherein 1≦x≦2.

Semiconductor material of carrier injection structures can be selected to establish p-n junctions with the semiconductor matrix of the electroluminescent layer. When an n-type semiconductor matrix of an electroluminescent layer is present, semiconductor material of the carrier injection structures is selected to be p-type, thereby providing numerous p-n junctions when the carrier injection structures contact the electroluminescent phase in a predetermined spatial distribution or pattern. For example, p-type carrier injection structures of CuₓS can contact a semiconductor matrix of n-type ZnS:Mn to provide a light emitting layer having a predetermined spatial distribution of p-n junctions. Alternatively, the carrier injection structures can comprise an n-type semiconductor material with the semiconductor matrix of the electroluminescent phase being p-type.

Additionally, in some embodiments, carrier injection structures are formed of metallic materials including, but not limited to, transition metals, transition metal alloys or conductive carbon materials such as carbon nanotubes, fullerenes, graphene or other carbon nanoparticles.

As described herein, the carrier injection structures are in contact with the semiconductor matrix of the electroluminescent phase in a predetermined spatial relationship. In having a predetermined spatial relationship with the semiconductor matrix of the electroluminescent phase, the locations and orientations of the carrier injection structures can be controlled to achieve increases in electroluminescent output and efficiency. In some embodiments, for example, the surface density of the carrier injection structures (carrier injection structures/unit area of semiconductor matrix) can be controlled to provide the desired electroluminescent output. Similarly, the volume density of the carrier injection structures (carrier injection structures/unit volume of semiconductor matrix) can be controlled to provide the desired electroluminescent output. Surface or volume density gradients of carrier injection structures can be provided by the predetermined spatial distribution leading to enhanced electroluminescence from the light emitting layer. In some embodiments, the predetermined spatial distribution provides one or two dimensional arrays of carrier injection structures in contact with the semiconductor matrix of the electroluminescent layer. The predetermined spatial distribution can provide carrier injection structures in any pattern not inconsistent with the objectives of the present invention. The predetermined spatial distribution of carrier injection structures can be selected according to several considerations including, but not limited to, the desired lighting characteristics of the electroluminescent device, frequency of the applied electric field, voltage of the alternating or direct current supplied to the electroluminescent device and the chemical identities of the carrier injection structures and semiconductor matrix.

Further, the predetermined spatial distribution can provide the carrier injection structures any desired orientation relative to the electric field applied by the first and second electrodes of the electroluminescent device. For example, in some embodiments, a carrier injection structure is provided an orientation wherein the major axis of the structure is parallel or substantially parallel to the direction of the applied electric field.

By controlling carrier injection structure location, geometry and/or orientation with a predetermined spatial distribution relative to the semiconductor matrix, light emitting layers described herein demonstrate a fundamental departure from prior electroluminescent architectures wherein carrier injection structures are formed by diffusion processes in a random or uncontrolled distribution, geometry and orientation at defect sites induced in the semiconductor matrix of the electroluminescent phase. Additionally, as described herein, injection structures can be formed of a variety of materials suitable for providing carriers to the semiconductor matrix of the electroluminescent phase. This also marks a fundamental departure from prior electroluminescent architectures restricted to material systems compatible with the diffusion processes employed to form the carrier injection structures at defect sites induced in the electroluminescent phase. The decoupling of material selection for injection structures from the processes used to form such structures greatly expands the architectural possibilities of electroluminescent devices described herein.

An electroluminescent device described herein further comprises first and second electrodes for application of an electric field to light emitting layer(s) of the device. The first and second electrodes can be independently selected from the group consisting of metals, alloys and electrically conducting radiation transmissive materials. Metals suitable for use as a first or second electrode can include aluminum, gold, copper, platinum, silver, nickel, iron or alloys thereof. Electrically conductive radiation transmissive materials, in some embodiments, are radiation transmissive conducting oxides. Radiation transmissive conducting oxides include indium tin oxide (ITO), gallium indium tin oxide (GITO), zinc indium tin oxide (ZITO), indium antimony oxide (IAO) and antimony tin oxide (ATO). Further, in some embodiments, an electrically conductive radiation transmissive material is polymeric, such as polyaniline (PANI), 3,4-polyethythlenedioxythiophene (PEDOT:PSS) or derivatives thereof. In some embodiments of an electroluminescent device described herein, at least one of the first and second electrodes is radiation transmissive. In some embodiments, both the first and second electrodes are radiation transmissive. Further, in some embodiments, the first and second electrodes are non-radiation transmissive.

The first electrode, in some embodiments, is electrically connected to the carrier injection structures of the light emitting layer. The first electrode, for example, can be commensurate or co-extensive with the predetermined spatial distribution of carrier injection structures. Alternatively, the first electrode is not commensurate with the carrier injection structures, contacting only a portion or section of each injection structure.

In other embodiments, the first electrode is electrically isolated from the carrier injection structures. The first electrode can be isolated from the carrier injection structures by one or more electrically insulating layers or dielectric layers. In some embodiments, an electrically insulating layer or dielectric layer comprises one or more inorganic oxides. Suitable inorganic oxides include transition metal oxides, alumina (Al₂O₃), silica (SiO₂) or mixtures thereof. In some embodiments, a dielectric layer comprises one or more polymeric materials. Suitable polymers for use as dielectric layers can comprise fluorinated polymers such as polyvinylidene fluoride (PVDF), poly(vinyl fluoride) (PVF), polytetrafluoroethylene (PTFE), perfluoropropylene, polychlorotrifluoroethylene (PCTFE) or copolymers and combinations thereof. A dielectric polymeric material can comprise polyacrylates including polyacrylic acid (PAA), poly(methacrylate) (PMA), poly(methylmethacrylate) (PMMA) or copolymers and combinations thereof. In some embodiments, an electrically insulating or dielectric polymeric material comprises polyethylenes, polypropylenes, polystyrenes, poly(vinylchloride), polycarbonates, polyamides, polyimides, or copolymers and combinations thereof.

The second electrode of an electroluminescent device described herein, in some embodiments, is electrically isolated from the semiconductor matrix of the electroluminescent phase. The second electrode can be isolated from the electroluminescent phase by one or more electrically insulating or dielectric layers. Suitable electrically insulating or dielectric layers can comprise any of the foregoing constructions for dielectric layers isolating the first electrode from the carrier injection structures.

As described herein, first and second electrodes, in some embodiments, apply an alternating electric field to light emitting layers of the electroluminescent devices. The applied alternating electric field can have any desired frequency not inconsistent with the objectives of the present invention. In some embodiments, the frequency of the alternating electric field ranges from about 16 Hz to about 16000 Hz. The frequency of the alternating electric field can be about 200 Hz, 400 Hz, 800 Hz or 1200 Hz. In one embodiment, the frequency of the alternating electric field is about 1600 Hz. Further, in some embodiments, the frequency of the alternating electric field ranges from about 1 MHz to about 1 GHz.

The alternating electric field can be applied to light emitting layers of electroluminescent devices described herein by providing alternating current to the electroluminescent devices. In some embodiments, for example, the operating voltage of an electroluminescent device described herein can be 120 VAC+/−10% of nominal. In some embodiments, the operating voltage of an electroluminescent device described herein ranges from about 10 VAC to about 220 VAC or from about 20 VAC to about 440 VAC. Alternatively, a direct current voltage is applied to the first and second electrodes to generate the electric field across the light emitting layers.

In another aspect, an electroluminescent described herein comprises a plurality of light emitting layers, the light emitting layers comprising charge carrier injection structures in contact with electroluminescent phases comprising luminescent centers in semiconductor matrices. Components of individual light emitting layers, such as charge carrier injection structures, luminescent centers and semiconductor matrix can have any of the constructions described above in this Section I. Further, the light emitting layers of the electroluminescent device, in some embodiments, are separated by one or more dielectric layers.

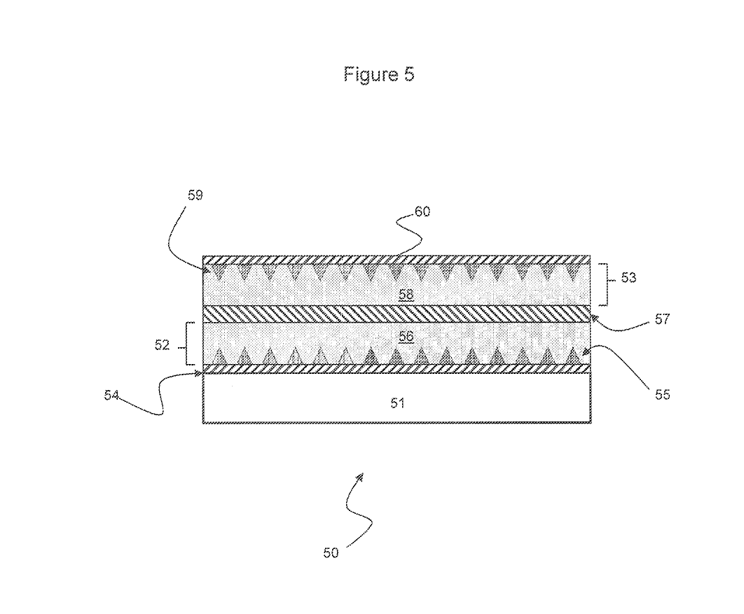

FIG. 5 illustrates a side cross-sectional view of an electroluminescent device comprising a plurality of light emitting layers according to one embodiment described herein. The electroluminescent device (50) of FIG. 5 comprises a radiation transmissive substrate (51) and a first light emitting layer (52) and a second light emitting layer (53) separated by an electrically insulating or dielectric layer (57). The first light emitting layer (52) comprises a first electrode (54) in electrical contact with carrier injection structures (55). The carrier injection structures (55) are in contact with an electroluminescent phase (56) in a predetermined spatial distribution. The predetermined spatial distribution, for example, can be a two-dimensional array of the carrier injection structures (55) in contact with the semiconductor matrix of the electroluminescent phase (56). The carrier injection structures can demonstrate a pyramidal or conical geometry wherein pyramid or cone vertices are oriented in a vertical dimension toward the electroluminescent phase (56).

The second light emitting layer (53) is positioned over the dielectric separation layer (57) with the electroluminescent phase (58) of the second light emitting layer (53) contacting the separation layer (57). Carrier injection structures (59) are in contact with the electroluminescent phase (58) in a predetermined spatial distribution. As in the first light emitting layer (52), the predetermined spatial distribution can be a one or two-dimensional array of the carrier injection structures (59) in contact with the semiconductor matrix of the electroluminescent phase (58). The carrier injection structures (59) can demonstrate a pyramidal or conical geometry wherein pyramid or cone vertices are oriented in a vertical dimension toward the electroluminescent phase (58). A second electrode (60) is in electrical communication with the carrier injection structures (59) of the second light emitting layer (53).

Electroluminescent devices described herein can demonstrate any light emitting surface area not inconsistent with the objectives of the present invention. In some embodiments, a light emitting device has a light emitting surface area on the tens or hundreds of cm². A light emitting device, in some embodiments, has a light emitting surface area on the order of m². Further, individual light emitting devices described herein can be combined to provide large light emitting surface areas. Individual light emitting devices, for example, can be combined in a tiled format for providing large light emitting surface areas.

### II. Methods of Making Electroluminescent Devices

In another aspect, methods of making electroluminescent devices are described herein. A method of making an electroluminescent device comprises providing a substrate and depositing over the substrate a first electroluminescent layer comprising carrier injection structures and an electroluminescent phase comprising luminescent centers in a semiconductor matrix, wherein the carrier injection structures are placed in contact with the electroluminescent phase in a predetermined spatial distribution.

Carrier injection structures can be placed in contact with the electroluminescent phase in a predetermined spatial distribution by various processes. In some embodiments, for example, the carrier injection structures are deposited directly on the semiconductor matrix of the electroluminescent phase in the predetermined spatial distribution. Deposition of carrier injection structures on the semiconductor matrix in the predetermined spatial distribution can be administered by one or more lithographic processes. A mask, for example, can be applied to the semiconductor matrix permitting the selective deposition of carrier injection structures on the matrix in the predetermined spatial distribution. The mask is subsequently removed by further processing.

In another embodiment, carrier injection structures are deposited on the substrate in the predetermined spatial distribution, and the semiconductor matrix of the electroluminescent phase is deposited directly over the carrier injections structures. Deposition of carrier injection structures on the substrate in the predetermined spatial distribution can also be administered by one or more lithographic processes. A mask can be applied to the substrate permitting selective deposition of carrier injection structures in the predetermined spatial distribution. The mask is subsequently removed, and the semiconductor matrix of the electroluminescent layer is deposited over the carrier injection structures.

The substrate on which the carrier injection structures are deposited can be a first electrode of the electroluminescent device. As described herein, the first electrode can be commensurate or co-extensive with the carrier injection structures, mirroring the predetermined spatial distribution of the structures. In such embodiments, the first electrode can be patterned on a dielectric substrate to match the predetermined spatial distribution of the carrier injection structures. The carrier injection structures are subsequently deposited over the patterned areas of the first electrode. Providing a first electrode commensurate with the carrier injection structures can be achieved in a single masking operation or multiple masking operations.

The first electrode, in some embodiments, is not commensurate with the carrier injection structures. For example, the carrier injection structures can be deposited such that only a portion or section of each injection structure contacts the first electrode. In one embodiment, the first electrode is deposited on a dielectric substrate such as glass. The carrier injection structures are deposited on the first electrode such that a section of each injection structure contacts the first electrode with the remaining portion of the injection structure contacting the dielectric substrate.

Alternatively, the substrate on which the carrier injection structures are deposited is solely a dielectric substrate, such as an inorganic oxide. In such embodiments, the first electrode of the electroluminescent device can be provided on the opposing side of the dielectric substrate.

A method of making an electroluminescent device further comprises providing a second electrode adjacent to the electroluminescent phase. The second electrode, in some embodiments, is deposited on the semiconductor matrix of the electroluminescent phase. Alternatively, one or more dielectric layers are positioned between the second electrode and the semiconductor matrix of the electroluminescent phase.

A method of making an electroluminescent device described herein can further comprise depositing over the first electroluminescent layer at least one additional electroluminescent layer comprising carrier injection structures and an electroluminescent phase comprising luminescent centers in a semiconductor matrix, wherein the carrier injection structures are placed in contact with the electroluminescent phase in predetermined spatial distribution. In some embodiments, an additional electroluminescent layer is separated from an underlying electroluminescent layer by one or more dielectric layers.

Light emitting layers having constructions described herein can be deposited by various thin film deposition techniques including atomic layer deposition (ALD), chemical vapor deposition (CVD) or physical vapor deposition (PVD). Suitable PVD methods can include sputtering or thermal evaporation. Similarly, the first and second electrodes can be deposited by sputtering or thermal evaporation.

Components of electroluminescent devices deposited according to methods described herein, including charge carrier injection structures, semiconductor matrices and luminescent centers of electroluminescent phases and first and second electrodes, can have any construction and/or properties described in Section I above.

### III. Methods of Generating Electromagnetic Radiation

In another aspect, methods of generating electromagnetic radiation are described herein. A method of generating electromagnetic radiation, in some embodiments, comprises providing an electroluminescent device comprising a first electrode, a second electrode and at least one light emitting layer comprising charge carrier injection structures in contact with an electroluminescent phase in a predetermined spatial distribution, wherein the electroluminescent phase comprises luminescent centers in a semiconductor matrix. An electric field is applied to the light emitting layer by the first and second electrodes, and charge carriers are injected into the semiconductor matrix by the charge carrier injection structures. In some embodiments, an alternating current voltage is applied to the device electrodes generating an alternating electric field across the light emitting layer. Depending on the cycle point of the alternating electric field, the injected charge carriers may be holes or electrons. The injected charge carriers are subsequently relaxed through one or more radiative relaxation pathways at the luminescent centers for the generation of electromagnetic radiation.

In some embodiments, the carrier injection structures are electrically connected to the first electrode thereby injecting charge carriers into the semiconductor matrix by current flow through the injection structures. Alternatively, the carrier injection structures are electrically isolated from the first electrode, and charge carrier injection is induced by electric field concentration at the carrier injection structures.

Electroluminescent devices for generating electromagnetic radiation according to methods described herein can have any construction and/or properties described in Section I herein.

Various embodiments of the invention have been described in fulfillment of the various objects of the invention. It should be recognized that these embodiments are merely illustrative of the principles of the present invention. Numerous modifications and adaptations thereof will be readily apparent to those skilled in the art without departing from the spirit and scope of the invention.

1. An electroluminescent device comprising:
a first electrode, a second electrode; and
at least one light emitting layer comprising charge carrier injection structures in contact with an electroluminescent phase in a predetermined spatial distribution, the electroluminescent phase comprising luminescent centers in a polycrystalline semiconductor matrix, wherein a dielectric layer is positioned between the polycrystalline semiconductor matrix and the second electrode.

2. The electroluminescent device of claim 1, wherein the charge carrier injection structures are electrically connected to the first electrode.

3. The electroluminescent device of claim 1 further comprising dielectric layers positioned between the first electrode and the light emitting layer and the second electrode and the light emitting layer.

4. The electroluminescent device of claim 1, wherein the charge carrier injection structures form p-n junctions with the semiconductor matrix.

5. The electroluminescent device of claim 1, wherein the charge carrier injection structures have a tapered geometry.

6. The electroluminescent device of claim 1, wherein the charge carrier injection structures have a minor structural axis on the order of nanometers or tens of nanometers and a major structural axis on the order of hundreds of nanometers.

7. The electroluminescent device of claim 1, wherein the charge carrier injection structures have geometry for providing electric fields at ends of the structures in the range of 10⁴ V/cm to 10⁶ V/cm.

8. The electroluminescent device of claim 1, wherein the charge carrier injection structures are substantially aligned with an electric field applied by the first and second electrodes.

9. The electroluminescent device of claim 1, wherein the charge carrier injection structures comprise a semiconductor material.

10. The electroluminescent device of claim 9, wherein the semiconductor material is p-type.

11. The electroluminescent device of claim 10, wherein the semiconductor material is CuₓS wherein 1≦x≦2.

12. The electroluminescent device of claim 2, wherein the predetermined spatial distribution is a one dimensional array of the charge injection structures.

13. The electroluminescent device of claim 2, wherein the predetermined spatial distribution is a two dimensional array of the charge injection structures.

14-19. (canceled)

20. A method of making an electroluminescent device comprising:
providing a substrate; and
depositing over the substrate an electroluminescent layer comprising charge carrier injection structures and an electroluminescent phase comprising luminescent centers in a polycrystalline semiconductor matrix, wherein the charge carrier injection structures are placed in contact with the electroluminescent phase in a predetermined spatial distribution.

21. The method of claim 20, wherein the charge carrier injection structures are placed in contact with the electroluminescent phase by depositing the charge carrier injection structures over the substrate in the predetermined spatial distribution and depositing the electroluminescent phase over the charge carrier injection structures.

22. The method of claim 21, wherein the charge carrier injection structures are deposited on the substrate comprising a first electrode.

23. The method of claim 21, wherein the substrate comprises a dielectric material.

24. The method of claim 20, wherein the charge carrier injection structures are placed in contact with the electroluminescent phase by depositing the electroluminescent phase over the substrate and depositing the charge carrier injection structures on the electroluminescent phase in the predetermined spatial distribution.

25. The method of claim 20 further comprising providing a first electrode adjacent to the charge carrier injection structures.

26. The method of claim 25, wherein the charge carrier injection structures are electrically connected to the first electrode.

27-33. (canceled)
